(19) United States
(12) Patent Application Publication
(10) Pub. No.: US 2023/0005934 A1
(43) Pub. Date: Jan. 5, 2023

(54) SEMICONDUCTOR MEMORY DEVICE

(71) Applicant: SK hynix Inc., Gyeonggi-do (KR)

(72) Inventors: Kyung Bo KIM, Gyeonggi-do (KR); Hyun Jung KIM, Gyeonggi-do (KR); Song KIM, Gyeonggi-do (KR)

(21) Appl. No.: 17/561,218

(22) Filed: Dec. 23, 2021

(30) Foreign Application Priority Data
Jun. 30, 2021 (KR) 10-2021-0085807

(51) Int. Cl. H01L 27/108; G11C 11/408

(52) U.S. Cl. CPC H01L 27/10897; H01L 27/10805; G11C 11/4085

(57) ABSTRACT

A semiconductor memory device comprises: a memory cell array including a word line stack including word lines vertically stacked; and a sub word line driver block including sub word lines disposed below an end portion of the word line stack, wherein the word lines and the sub word lines extend in directions, respectively, crossing each other.

### CROSS-REFERENCE TO RELATED APPLICATIONS

The present application claims priority to Korean Patent Application No. 10-2021-0085807, filed on Jun. 30, 2021, which is incorporated herein by reference in its entirety.

### BACKGROUND

### 1. Field

Present invention relates to a semiconductor device and, more particularly, to a semiconductor memory device.

### 2. Description of the Related Art

Integration degree of two-dimensional semiconductor memory devices is mainly determined by the area occupied by memory cells. Thus, the integration degree is mainly affected by the level of a fine-pattern fabrication technology. The integration degree of two-dimensional semiconductor memory devices is still increasing, but the increase is limited because fabricating finer patterns requires highly expensive tools. Accordingly, three-dimensional (3D) semiconductor memory devices having three-dimensionally arranged memory cells are being suggested.

### SUMMARY

Various embodiments of the present invention provide a highly integrated semiconductor memory device.

A semiconductor memory device according to an embodiment of the present invention comprises: a memory cell array including a word line stack including word lines vertically stacked; and a sub word line driver block including sub word lines disposed below an end portion of the word line stack, wherein the word lines and the sub word lines extend in directions, respectively, crossing each other.

A memory cell array according to an embodiment of the present invention comprises: a plurality of memory cells, each of the memory cells including a laterally oriented active layer, a vertically oriented bit line connected to one side of the laterally oriented active layer, and a capacitor connected to another side of the laterally oriented active layer; and a word line stack including a plurality of double word lines vertically stacked, each double word line including an upper and a lower word line facing each other with a corresponding laterally oriented active layer disposed therebetween, wherein opposite edge portions of each of the double word lines have a step shape defining contact portions for placing word line contact pads connecting the double word lines to corresponding sub word line drivers via interconnect metal lines.

By arranging word lines of a memory cell array and sub word lines of a sub word line driver to cross each other, the present invention may simplify interconnections which connect the word lines and the sub word lines.

### BRIEF DESCRIPTION OF THE DRAWINGS

FIG. 1 is a schematic perspective view illustrating a memory cell of a semiconductor memory device according to an embodiment of the present invention.

FIG. 2A is a cross-sectional view of a semiconductor device taken along line A1-A1′ of FIG. 1.

FIG. 2B is an enlarged view of a transistor TR.

FIG. 3 is a schematic perspective view illustrating a semiconductor memory device according to an embodiment of the present invention.

FIG. 4 is a cross-sectional view illustrating edge portions of double word lines of FIG. 3.

FIG. 5 is a schematic cross-sectional view illustrating a memory cell array of a semiconductor memory device according to an embodiment of the present invention.

FIG. 6 is an equivalent circuit diagram illustrating a sub word line driver block according to an embodiment of the present invention.

FIG. 7 is a plan view illustrating the sub word line driver block of FIG. 6.

FIG. 8 is a schematic perspective view illustrating a connection structure between sub word lines and double word lines.

FIG. 9 is a schematic perspective view illustrating a semiconductor memory device according to another embodiment of the present invention.

### DETAILED DESCRIPTION

Various embodiments described herein will be described with reference to cross-sectional views, plan views and block diagrams, which are ideal schematic views of the present invention. Therefore, the structures of the drawings may be modified by fabricating technology and/or tolerances. Various embodiments of the present invention are not limited to the specific structures shown in the drawings, but include any changes in the structures that may be produced according to the fabricating process. Also, any regions and shapes of regions illustrated in the drawings have schematic views, which are intended to illustrate specific examples of structures of regions of the various elements, and are not intended to limit the scope of the invention.

In an embodiment to be described below, memory cell density may be increased and parasitic capacitance may be decreased by vertically stacking memory cells.

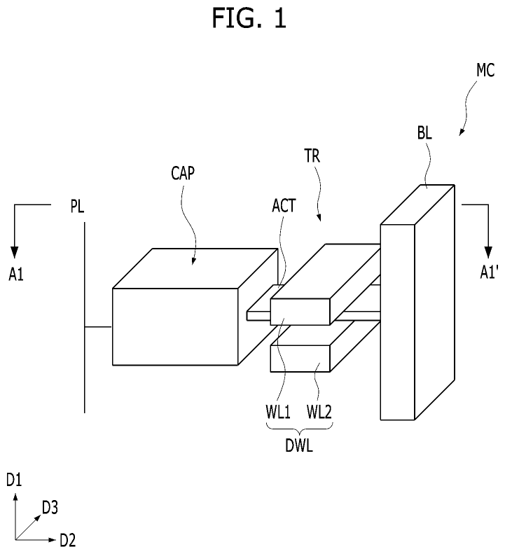

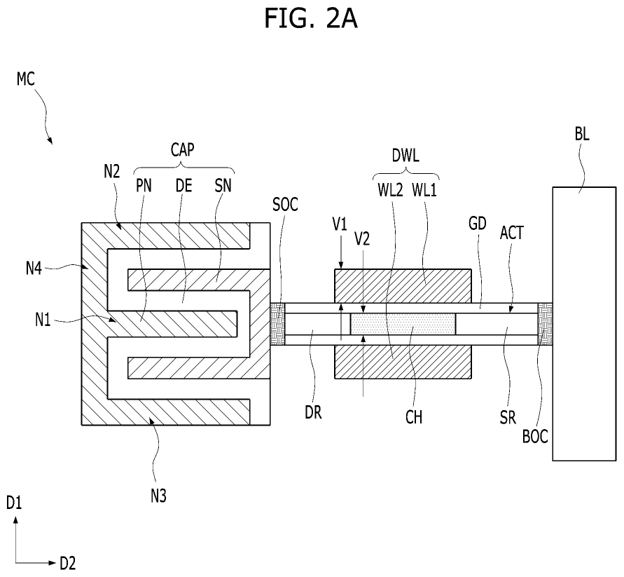

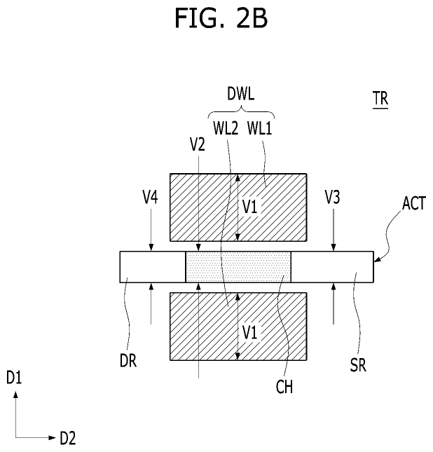

FIG. 1 is a schematic perspective view of a memory cell of a semiconductor memory device according to an embodiment of the present invention. FIG. 2A is a cross-sectional view of the semiconductor memory device taken along the line A1-A1′ of FIG. 1. FIG. 2B is an enlarged view of the transistor TR.

Referring to FIGS. 1, 2A, and 2B, the semiconductor memory device according to an embodiment of the present invention may include a memory cell MC. The memory cell MC may include a bit line BL, a transistor TR, and a capacitor CAP. The transistor TR may include an active layer ACT, a gate dielectric layer GD, and a double word line DWL. The capacitor CAP may include a storage node SN, a dielectric layer DE, and a plate node PN.

The bit line BL may have a pillar shape extending in a first direction D1. The active layer ACT may have a bar-shape extending in a second direction D2 crossing the first direction D1. The double word line DWL may have a line-shape extending in a third direction D3 crossing both the first and the second directions D1 and D2. The plate node PN of the capacitor CAP may be connected to the plate line PL.

The bit line BL may be vertically oriented along the first direction D1. The bit line BL may be referred to as a vertically oriented bit line, a vertically extended bit line, or a pillar shape bit line. The bit line BL may include a conductive material. The bit line BL may include a silicon-based material, a metal-based material, or a combination thereof. The bit line BL may include polysilicon, metal, metal nitride, metal silicide, or a combination thereof. The bit line BL may include polysilicon, titanium nitride, tungsten, or a combination thereof. For example, the bit line BL may include polysilicon doped with N-type impurities or titanium nitride (TiN). The bit line BL may include a stack of titanium nitride and tungsten (TiN/W).

The transistor TR may include an active layer ACT, a gate dielectric layer GD, and a double word line DWL. The double word line DWL may extend in the third direction D3, and the active layer ACT may extend in the second direction D2. The active layer ACT may be laterally arranged from the bit line BL. The active layer ACT may include a thin-body channel CH, a first source/drain region SR disposed between the thin-body channel CH and the bit line BL, and a second source/drain region DR disposed between the thin thin-body channel CH and the capacitor CAP. The double word line DWL may include a first word line WL1 and a second word line WL2. The first word line WL1 and the second word line WL2 may face each other with the active layer ACT interposed therebetween. A gate dielectric layer GD may be formed on upper and lower surfaces of the active layer ACT.

The active layer ACT may include a semiconductor material or an oxide semiconductor material. For example, the active layer ACT may include silicon, germanium, silicon-germanium, or indium gallium zinc oxide (IGZO).

The first source/drain region SR and the second source/drain region DR may be doped with impurities of the same conductivity type. The first source/drain region SR and the second source/drain region DR may be doped with an N-type impurity or a P-type impurity. The first source/drain region SR and the second source/drain region DR may include at least one impurity selected from the group consisting of arsenic (As), phosphorus (P), boron (B), indium (In), and a combination thereof. A first side of the first source/drain region SR may contact the bit line BL, and a second side of the first source/drain region SR may contact the thin-body channel CH. A first side of the second source/drain region DR may contact the storage node SN, and a second side of the second source/drain region DR may contact the thin-body channel CH. The second side of the first source/drain region SR and the second side of the second source/drain region DR may partially overlap side surfaces of the first and second word lines WL1 and WL2. A lateral length of the thin-body channel CH in the second direction D2 may be greater than lateral lengths of the first and second source/drain regions SR and DR in the second direction D2. In another embodiment (not shown), the lateral length of the thin-body channel CH in the second direction D2 may be smaller than the lateral lengths of the first and second source/drain regions SR and DR in the second direction D2. A bit line side-ohmic contact BOC may be formed between the first source/drain region SR and the bit line BL. The bit line side-ohmic contact BOC may be formed when the metal of the bit line BL reacts with the silicon of the first source/drain region SR. The bit line side-ohmic contact BOC may include metal silicide, and may be formed on one edge of the active layer ACT, that is, on the first side of the first source/drain region SR. A storage node side-ohmic contact SOC may be formed between the second source/drain region DR and the storage node SN. The storage node side-ohmic contact SOC may include metal silicide, and may be formed on the other edge of the active layer ACT, that is, on the first side of the second source/drain region DR. The storage node side-ohmic contact SOC may be formed when the metal of the storage node SN reacts with the silicon of the second source/drain region DR.

The gate dielectric layer GD may include silicon oxide, silicon nitride, metal oxide, metal oxynitride, metal silicate, a high-k material, a ferroelectric material, an anti-ferroelectric material, or a combination thereof. The gate dielectric layer GD may include SiO₂, Si₃N₄, HfO₂, Al₂O₃, ZrO₂, AlON, HfON, HfSiO, HfSiON, or a combination thereof.

The first and second word lines WL1 and WL2 of the double word line DWL may include a metal, a metal nitride, a metal silicide, a metal mixture, a metal alloy, or a semiconductor material. The double word line DWL may include titanium nitride, tungsten, polysilicon, or a combination thereof. For example, the double word line DWL may include a TiN/W stack in which titanium nitride and tungsten are sequentially stacked. The double word line DWL may include an N-type work function material or a P-type work function material. The N-type work function material may have a low work function of 4.5 eV or less, and the P-type work function material may have a high work function of 4.5 eV or more.

The capacitor CAP may be laterally disposed from the transistor TR along the second direction D2. The capacitor CAP may include the storage node SN laterally extending from the active layer ACT along the second direction D2. The capacitor CAP may further include a dielectric layer DE and a plate node PN which are formed over the storage node SN. The storage node SN, the dielectric layer DE, and the plate node PN may be laterally arranged along the second direction D2. The storage node SN may have a laterally oriented cylinder-shape. The dielectric layer DE may conformally cover the cylinder inner wall and the cylinder outer wall of the storage node SN. The plate node PN may have a shape extending into a cylinder inner wall and a cylinder outer wall of the storage node SN on the dielectric layer DE. The plate node PN may have an “E” shape having a vertical bar and three horizontal bars extending from the vertical bar with a middle horizontal bar extending into the cylinder inner wall of the storage node and the outer horizontal bars extending around the cylinder outer wall of the storage node SN on the dielectric layer DE. The plate node PN may be connected to the plate line PL. More specifically, the vertical bar of the plate node PN may be connected to the plate line PL. The storage node SN may be electrically connected to the second source/drain region DR and the storage node-side ohmic contact SOC.

The storage node SN may have a three-dimensional structure, and the storage node SN of the three-dimensional structure may be laterally oriented to the second direction D2. As an example of the three-dimensional structure, the storage node SN may have a cylinder shape. In another embodiment, the storage node SN may have a pillar shape or a pylinder shape. The pylinder shape may refer to a structure in which a pillar shape and a cylinder shape are merged. The top surface of the storage node SN may be positioned at the same level as the top surface of the first word line WL1. The bottom surface of the storage node SN may be positioned at the same level as the bottom surface of the second word line WL2.

The plate node PN may include an inner node N1 and outer nodes N2, N3, and N4. The inner node N1 and the outer nodes N2, N3, and N4 may be interconnected. The inner node N1 may be disposed inside the cylinder of the storage node SN. The outer nodes N2 and N3 may be disposed outside the cylinder of the storage node SN with the dielectric layer DE interposed therebetween. The outer node N4 may interconnect the inner node N1 and the outer nodes N2 and N3. The outer nodes N2 and N3 may be disposed to surround the cylinder outer wall of the storage node SN. The outer node N4 may be connected to the plate line PL.

The storage node SN and the plate node PN may include a metal, a noble metal, a metal nitride, a conductive metal oxide, a conductive noble metal oxide, a metal carbide, a metal silicide, or a combination thereof. For example, the storage node SN and the plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a stack of tungsten nitride/tungsten (WN/W) stack. The plate node PN may include a combination of a metal-based material and a silicon-based material. For example, the plate node PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the cylinder of the storage node SN, titanium nitride (TiN) may be used as the plate node PN of the capacitor CAP, and tungsten nitride may be a low-resistivity material.

The dielectric layer DE may include silicon oxide, silicon nitride, a high-k material, or a combination thereof. The high-k material may have a higher dielectric constant than silicon oxide. Silicon oxide (SiO₂) may have a dielectric constant of about 3.9, and the dielectric layer DE may include a high-k material having a dielectric constant of 4 or more. The high-k material may have a dielectric constant of about 20 or more. The high dielectric constant material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In another embodiment, the dielectric layer DE may be formed of a composite layer including two or more layers of the aforementioned high-k material.

The dielectric layer DE may be formed of a zirconium (Zr)-based oxide. The dielectric layer DE may have a stack structure including zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. In another embodiment, the dielectric layer DE may be formed of hafnium-based oxide. The dielectric layer DE may have a stack structure including hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, the aluminum oxide (Al₂O₃) may have a larger band gap than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a band gap larger than that of a high-k material. The dielectric layer DE may include silicon oxide (SiO₂) as a high bandgap material other than aluminum oxide (Al₂O₃). Since the dielectric layer DE includes a high bandgap material, leakage current may be suppressed. The high bandgap material may be thinner than the high-k material. In another embodiment, the dielectric layer DE may include a laminated structure in which a high-k material and a high-bandgap material are alternately stacked. For example, the dielectric layer DE may include ZAZA (ZrO₂/Al₂O₃/ZrO₂/Al₂O₃), ZAZAZ (ZrO₂/Al₂O₃/ZrO₂/Al₂O₃/ZrO₂), HAHA (HfO₂/Al₂O₃/HfO₂/Al₂O₃), or HAHAH (HfO₂/Al₂O₃/HfO₂/Al₂O₃/HfO₂). In the laminated structures described above, aluminum oxide (Al₂O₃) may be thinner than zirconium oxide and hafnium oxide.

In another embodiment, the dielectric layer DE may include a stack structure, a laminate structure, or a mutual mixing structure including zirconium oxide, hafnium oxide, or aluminum oxide.

In another embodiment, an interface control layer for improving leakage current may be further formed between the storage node SN and the dielectric layer DE. The interface control layer may include titanium oxide (TiO₂). The interface control layer may also be formed between the plate node PN and the dielectric layer DE.

The capacitor CAP may include a metal-insulator-metal (MIM) capacitor. The storage node SN and the plate node PN may include a metal-based material.

The capacitor CAP may be replaced with other data storage materials. For example, the data storage material may include a phase change material, a magnetic tunnel junction (MTJ), or a variable resistor material.

Referring back to FIGS. 2A and 2B, the transistor TR is a cell transistor and may have a double word line DWL. In the double word line DWL, the first word line WL1 and the second word line WL2 may have the same electric potential. For example, the first word line WL1 and the second word line WL2 may form a pair to drive one memory cell MC. The same word line driving voltage may be applied to the first word line WL1 and the second word line WL2. As such, the memory cell MC according to the present embodiment may have a structure in which the first and second word lines WL1 and WL2, or the double word line DWL, are disposed adjacent to one thin-body channel CH.

In another embodiment, the first word line WL1 and the second word line WL2 may have different electric potentials. For example, a word line driving voltage may be applied to the first word line WL1, and a ground voltage may be applied to the second word line WL2. The second word line WL2 may be referred to as a back word line or a shield word line. In another embodiment, a ground voltage may be applied to the first word line WL1, and a word line driving voltage may be applied to the second word line WL2.

The first and second word lines WL1 and WL2 may each have a first thickness V1 in the first direction D1, and the active layer ACT may have a second thickness V2 in the first direction D1. The first thickness V1 and the second thickness V2 may refer to a vertical thickness. The second thickness V2 may be smaller than the first thickness V1. The active layer ACT may have a thickness smaller than that of the first and second word lines WL1 and WL2. The active layer ACT may be referred to as a thin-body active layer.

The thin-body channel CH may have a second thickness V2 in the first direction D1. The second thickness V2 of the thin-body channel CH may be smaller than that of the first and second word lines WL1 and WL2. The second thickness V2 of the thin-body channel CH may be greater than that of the gate dielectric layer GD.

The first source/drain region SR may have a third thickness V3 in the first direction D1, and the second source/drain region DR may have a fourth thickness V4 in the first direction D1. The third thickness V3 of the first source/drain region SR, the fourth thickness V4 of the second source/drain region DR, and the second thickness V2 of the thin-body channel CH may be the same. The third thickness V3 of the first source/drain region SR and the fourth thickness V4 of the second source/drain region DR may be smaller than the first thickness of the first and second word lines WL1 and WL2.

The second thickness V2 of the thin-body channel CH may be 10 nm or less (1 to 10 nm). The third thickness V3 of the first source/drain region SR and the fourth thickness V4 of the second source/drain region DR may be 10 nm or less. In another embodiment, the third thickness V3 of the first source/drain region SR and the fourth thickness V4 of the second source/drain region DR may be smaller than the first thickness V1 of the first and second word lines WL1 and WL2 and greater than the second thickness V2 of the thin-body channel CH.

An upper surface and a lower surface of the active layer ACT may have a flat surface. That is, an upper surface and a lower surface of the active layer ACT may be parallel to each other in the second direction D2.

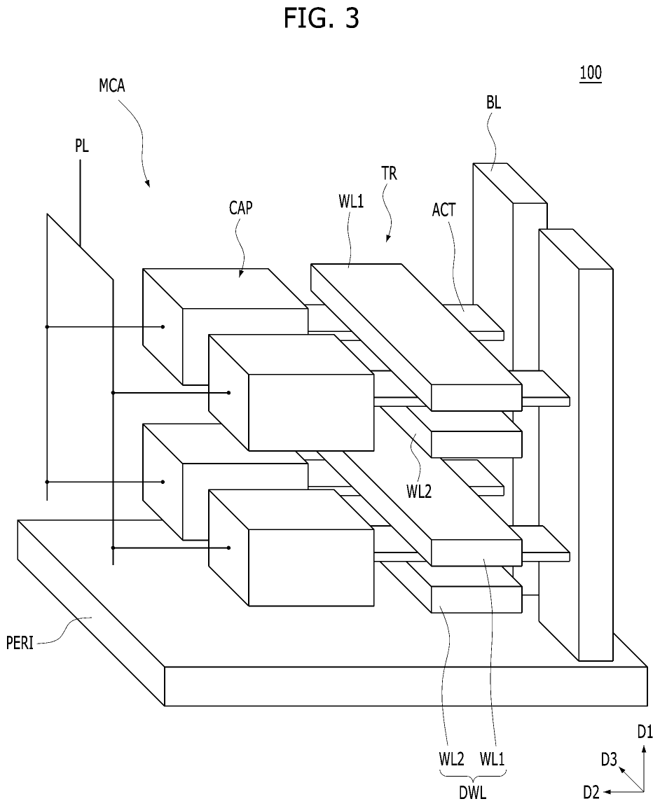

FIG. 3 is a schematic perspective view of a semiconductor memory device according to an embodiment of the present invention.

Referring to FIG. 3, the semiconductor memory device 100 may include a memory cell array MCA. A plurality of memory cells MC of FIGS. 1, 2A and 2B may be arranged in the first to third directions D1, D2, and D3 to form a multi-layered memory cell array MCA. FIG. 3 illustrates a three-dimensional memory cell array composed of four memory cells. In the memory cell array MCA, two double word lines DWL may be vertically stacked in the first direction D1. Each double word line DWL may include a pair of the first word line WL1 and the second word line WL2. Between the first word line WL1 and the second word line WL2, a plurality of active layers ACT may be arranged laterally in the third direction D3 being spaced apart from each other. Referring to FIG. 2A, the thin-body channel CH of the active layer ACT may be disposed between the first word line WL1 and the second word line WL2.

The memory cell array MCA may include a three-dimensional array of memory cells.

The semiconductor memory device 100 may further include a substrate PERI, and the substrate PERI may include a peripheral circuit portion. Hereinafter, the substrate PERI will be abbreviated as a peripheral circuit portion PERI. The bit lines BL of the memory cell array MCA may be vertically oriented with respect to the surface of the peripheral circuit portion PERI along the first direction D1. The double word lines DWL may be oriented parallel to the surface of the peripheral circuit portion PERI along the third direction D3. The peripheral circuit portion PERI may be located at a lower level than the memory cell array MCA. This may be referred to as a cell over PERI (COP) structure.

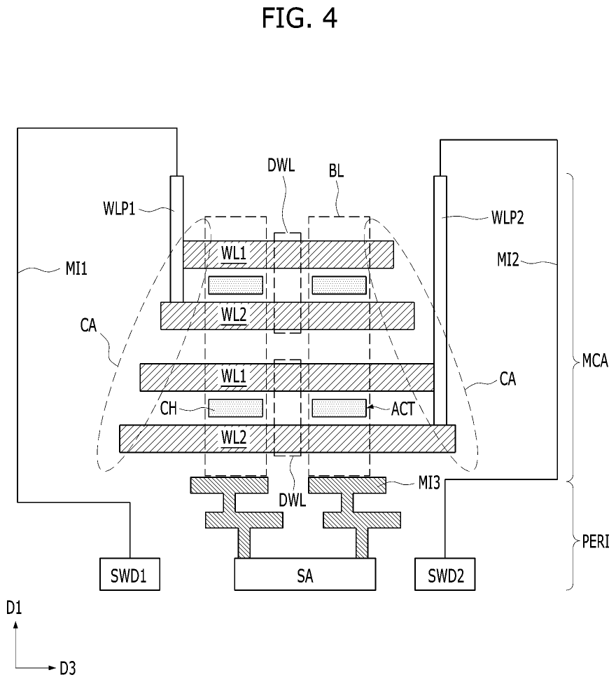

FIG. 4 is a cross-sectional view illustrating edge portions of double word lines of FIG. 3.

Referring to FIG. 4, both edge portions of each of the double word lines DWL may have a step shape, and the step shape may define contact portions CA. Each of the first word lines WL1 and the second word lines WL2 may include edge portions on both sides, that is, contact portions CA. Each of the contact portions CA may have a step shape.

Word line pads WLP1 and WLP2 may be respectively connected to the contact portions CA. The first word line pad WLP1 may be connected to the contact portions CA of the first and second word lines WL1 and WL2 disposed at an upper level, and the second word line pad WLP2 may be connected to the contact portions CA of the first and second word lines WL1 and WL2 at a lower level. The first and second word lines WL1 and WL2 at the upper level may be interconnected by the first word line pad WLP1. The first and second word lines WL1 and WL2 at the lower level may be interconnected by the second word line pad WLP2.

The peripheral circuit portion PERI may include at least one control circuit for driving the memory cell array MCA. At least one control circuit of the peripheral circuit portion PERI may include an N-channel transistor, a P-channel transistor, a CMOS circuit, or a combination thereof. At least one control circuit of the peripheral circuit portion PERI may include an address decoder circuit, a read circuit, a write circuit, and the like. At least one control circuit of the peripheral circuit portion PERI may include a planar channel transistor, a recess channel transistor, a buried gate transistor, and a fin channel transistor (FinFET), and the like.

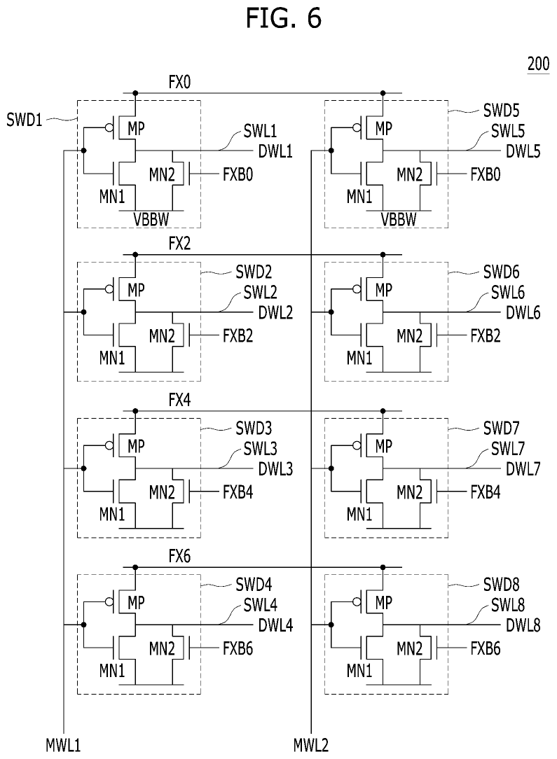

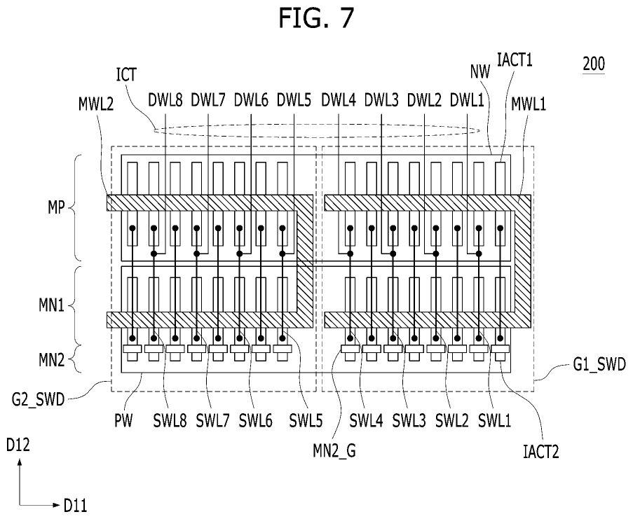

For example, the peripheral circuit portion PERI may include a sub word line driver block and a sense amplifier SA. The sub word line driver block will be illustrated with reference to FIGS. 6 and 7, which will be described below. The sub word line driver block may include a plurality of sub word line drivers. In FIG. 4, the sub word line driver block may include first and second sub word line drivers SWD1 and SWD2. The first and second word lines WL1 and WL2 at the upper level may be connected to the first sub word line driver SWD1 through the first word line pads WLP1 and a first interconnection MI1. The first and second word lines WL1 and WL2 at the lower level may be connected to the second sub word line driver SWD2 through the second word line pads WLP2 and a second interconnection MI2. The bit lines BL may be connected to the sense amplifier SA through a third interconnection MI3. The third interconnection MI3 may have a multi-level metal structure including a plurality of vias and a plurality of metal lines.

The double word lines DWL may be driven by the first and second sub word line drivers SWD1 and SWD2. The sub word line drivers SWD1 and SWD2 may be disposed below the step structures of the double word lines DWL.

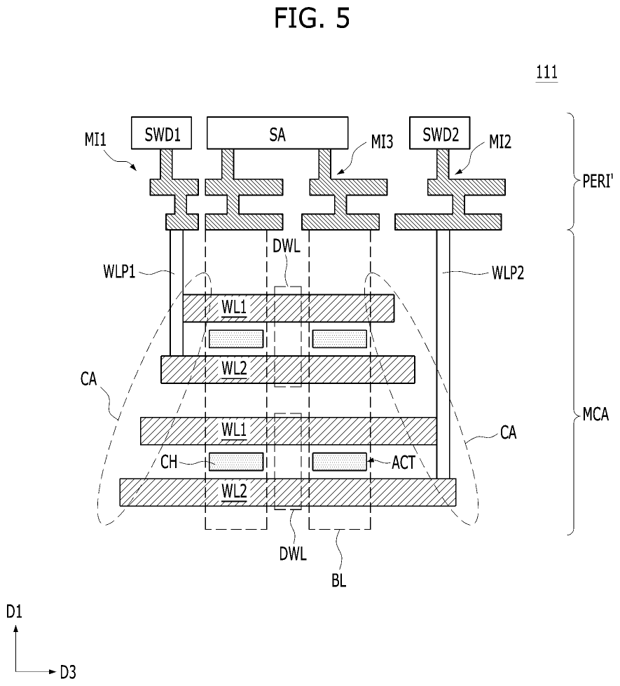

FIG. 5 is a schematic cross-sectional view of a memory cell array of a semiconductor memory device according to another embodiment of the present invention. FIG. 5 illustrates a semiconductor memory device 111 having a Peri Over Cell (POC) structure. In FIG. 5, detailed descriptions of duplicate components with those of FIG. 4 will be omitted.

Referring to FIG. 5, the semiconductor memory device 111 may include a memory cell array MCA and a peripheral circuit portion PERI′. The peripheral circuit portion PERI′ may be positioned at a higher level than the memory cell array MCA. This may be referred to as a POC (PERI over Cell) structure.

The peripheral circuit portion PERI′ may include first and second sub word line drivers SWD1 and SWD2 and a sense amplifier SA. The upper-level double word lines DWL may be connected to the first sub word line driver SWD1 through the first word line pads WLP1 and the first interconnection MI1. The lower-level double word lines DWL may be connected to the second sub word line driver SWD2 through the second word line pads WLP2 and the second interconnection MI2. The bit lines BL may be connected to the sense amplifier SA through the third interconnection MI3. The first to third interconnections MI1, MI2, and MI3 may have a multi-level metal structure including a plurality of vias and a plurality of metal lines.

FIG. 6 is an equivalent circuit diagram illustrating a sub word line driver block according to an embodiment of the present invention. FIG. 7 is a plan view illustrating the sub word line driver block of FIG. 6.

Referring to FIGS. 6 and 7, the sub word line driver block 200 may include a plurality of sub word line drivers SWD1 to SWD8. The double word lines DWL1 to DWL8 may be driven by the sub word line drivers SWD1 to SWD8 disposed in the sub word line driver block 200.

The sub word line drivers SWD1 to SWD8 may be electrically connected to respective double word lines DWL1 to DWL8 through respective sub word lines SWL1 to SWL8 and the interconnections ICT.

The sub word line driver block 200 may include a first group sub word line driver G1_SWD and a second group sub word line driver G2_SWD. The first group sub word line driver G1_SWD may include first to fourth sub word line drivers SWD1, SWD2, SWD3, and SWD4. The second group sub-word line driver G2_SWD may include fifth to eighth sub-word line drivers SWD5, SWD6, SWD7, and SWD8.

The sub word line drivers SWD1, SWD2, SWD3, and SWD4 of the first group sub word line driver G1_SWD may be driven in response to a first main word line MWL1. The sub word line drivers SWD5, SWD6, SWD7, and SWD8 of the second group sub word line driver G2_SWD may be driven in response to a second main word line MWL2.

The sub word line drivers SWD1 to SWD8 are activated by the first sub word line driver enable signals FX0, FX2, FX4, and FX6 and the second sub word line driver enable signals FXB0, FXB2, FXB4, and FXB6. The activated sub-word line drivers SWD1 to SWD8 may drive the double word lines DWL1 to DWL8, respectively.

The first group sub word line driver G1_SWD and the second group sub word line driver G2_SWD may receive inputs from the first sub word line driver enable signals FX0, FX2, FX4, and FX6 and the second sub word line driver enable signals FXB0, FXB2, FXB4, and FXB6. The second sub-word line driver enable signals FXB0 to FXB6 may be inversion signals of the first sub word line driver enable signals FX0 to FX6.

Each of the sub word line drivers SWD1 to SWD8 may include a PMOSFET MP, first and second NMOSFETs MN1 and MN2, and a sub word line SWL1 to SWL8. Taking the first sub word line driver SWD1 as an example, the gate of the PMOSFET MP and the gate of the first NMOSFET MN1 may be connected to the first main word line ML1. The drain of the PMOSFET MP may receive the first sub word line driver enable signal FX0, and the source of the PMOSFET MP may be connected to the first sub word line SWL1. A source of the first NMOSFET MN1 may be connected to the ground potential VBBW, and the drain of the first NMOSFET MN1 may be connected to the first sub word line SWL1. The gate of the second NMOSFET MN2 may receive the second sub word line driver enable signal FXB0, the source of the second NMOSFET MN2 may be connected to the ground potential VBBW, and the drain of the second NMOSFET MN2 may be connected to the first sub word line SWL1. The gate of the PMOSFET MP and the gate of the first NMOSFET MN1 may be commonly connected to the first main word line MWL1, and the source of the PMOSFET MP, the drain of the first NMOSFET MN1, and the drain of the second NMOSFET MN2 may be commonly connected to the first sub word line SWL1. The first sub word line SWL1 may be connected to the first double word line DWL1 through the interconnection ICT. The first double word line DWL1 and the first sub word line SWL1 may extend in directions crossing each other. For example, the first double word line DWL1 may extend in the first direction D11, and the first sub word line SWL1 may extend in the second direction D12 crossing the first direction D11.

The PMOSFET MP, the first and second NMOSFETs MN1 and MN2 of all the sub word line drivers SWD1 to SWD8 may have the same structure.

Referring back to FIG. 7, each of the main word lines MWL1 and MWL2 may extend in the first direction D11. Each of the main word lines MWL1 and MWL2 may have a bent shape, for example, a ‘⊃’ shape. In another embodiment, each of the main word lines MWL1 and MWL2 may have a line-type or an island-type and be connected through interconnections. Portions of the main word lines MWL1 and MWL2 may extend in a direction crossing the sub word lines SWL1 to SWL8. The main word lines MWL1 and MWL2 may refer to gates of the PMOSFET MP and the first NMOSFET MN1. The gates MN2_G of the second NMOSFETs MN2 may be independently formed from each other.

The sub-word lines SWL1 to SWL8 may be disposed at a higher level than the main word lines MWL1 and MWL2.

The PMOSFETs MP of the sub word line drivers SWD1 to SWD8 may include an N-type well NW and island-type active layers IACT1. The island-type active layers IACT1 of the PMOSFETs MP may be defined in the N-type well NW and may extend in the second direction D12. The first and second NMOSFETs MN1 and MN2 of the sub word line drivers SWD1 to SWD8 may include a P-type well PW and island-type active layers IACT2. The island-type active layers IACT2 of the first and second NMOSFETs MN1 and MN2 may be defined in the P-type well PW and may extend in the second direction D12. The first and second NMOSFETs MN1 and MN2 may share the island-type active layer IACT2.

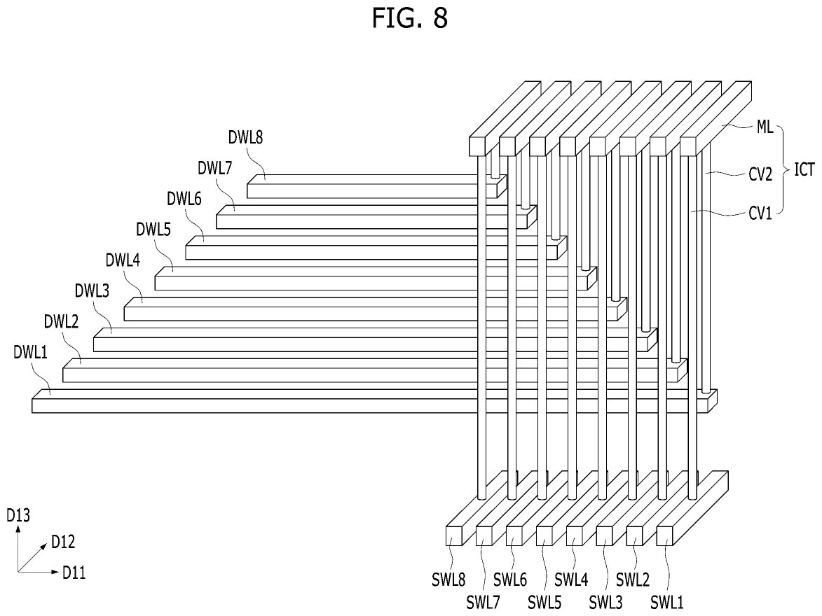

FIG. 8 is a schematic perspective view illustrating a connection structure between double word lines and sub word lines according to an embodiment of the present invention.

Referring to FIG. 8, double word lines DWL1 to DWL8 may extend along the first direction D11, and the double word lines DWL1 to DWL8 may be vertically stacked along the third direction D13.

The sub word lines SWL1 to SWL8 may extend in the second direction D12. The first direction D11 and the second direction D12 may cross each other, the second direction D12 and the third direction D13 may cross each other, and the first direction D11 and the third direction D13 may cross each other. The sub word lines SWL1 to SWL8 and the double word lines DWL1 to DWL8 may cross each other.

The lengths of the sub word lines SWL1 to SWL8 may be smaller than the lengths of the double word lines DWL1 to DWL8.

The sub word lines SWL1 to SWL8 and the double word lines DWL1 to DWL8 may be electrically connected to each other through the interconnections ICT. Each of the interconnections ICT may include a plurality of vias CV1 and CV2 and metal interconnections ML. The metal interconnections ML may be parallel to each other. The metal interconnections ML may extend in the second direction D12. The sub word lines SWL1 to SWL8 and the metal interconnections ML may extend in the same direction. In another embodiment, the metal interconnections ML may extend in the first direction D11. The sub word lines SWL1 to SWL8 may be disposed at a level lower than the double word lines DWL1 to DWL8, and the metal interconnections ML may be disposed at a higher level than the double word lines DWL1 to DWL8. The sub word lines SWL1 to SWL8 may be disposed at a level lower than the double word line DWL1 which is disposed at the lowest level among the double word lines DWL1 to DWL 8, and the metal interconnections ML may be disposed at a higher level than the double word line DWL8 which is disposed at the highest level among the double word lines DWL1 to DWL8.

The first and second NMOSFETs MN1 and MN2 and the PMOSFETs of the sub word line drivers SWD1 to SWD8 may be arranged to be advantageous for interlocking one step pitch of the stepped structure of the double word lines DWL1 to DWL8. The first and second NMOSFETs MN1 and MN2 and the PMOSFET MP may be disposed in a direction vertical to the sub word lines SWL1 to SWL8 on the same plane. In addition, the sub word lines SWL1 to SWL8 may be disposed to vertically cross the double word lines DWL1 to DWL8.

As described above, the interconnections ICT for connecting the double word lines DWL1 to DWL8 to the sub word line drivers SWD1 to SWD8 may be simplified because the sub word lines SWL1 to SWL8 and the double word lines DWL1 to DWL8 are arranged to cross each other vertically. In addition, since the sub word lines SWL1 to SWL8 and the double word lines DWL1 to DWL8 are arranged to be vertical to each other, a large width of the interconnections ICT can be achieved. Thus, process difficulty may be reduced by securing a large width of the interconnections ICT and minimizing the use of bent-shape interconnections ICT.

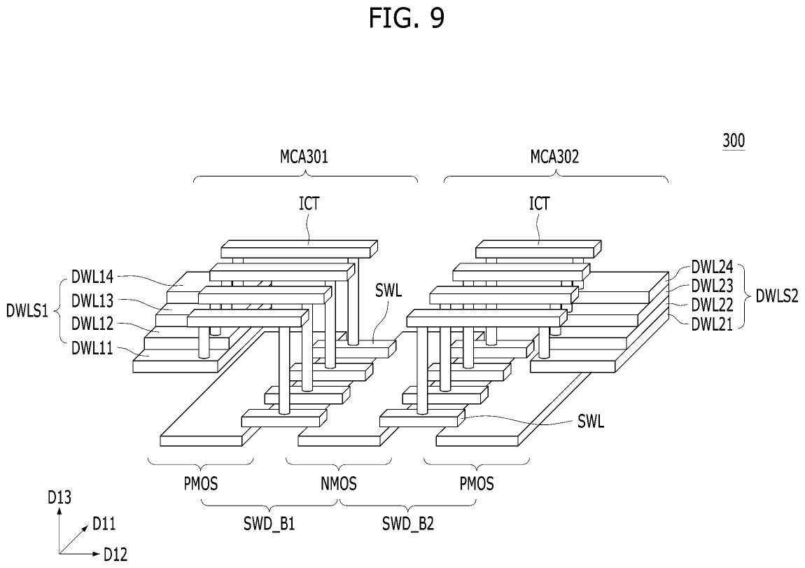

FIG. 9 is a schematic perspective view illustrating a semiconductor memory device according to another embodiment of the present invention.

Referring to FIG. 9, the semiconductor memory device 300 may include first and second memory cell arrays MCA301 and MCA302, and sub word line driver blocks SWD_B1 and SWD_B2 disposed at a level lower than the first and second memory cell arrays MCA301 and MCA302. The first memory cell array MCA301 may include a first double word line stack DWLS1, and the second memory cell array MCA302 may include a second double word line stack DWLS2. The first double word line stack DWLS1 may include a plurality of double word lines DWL11 to DWL14, and the second double word line stack DWLS2 may include a plurality of double word lines DWL21 to DWL24. The number of double word lines in the first and second double word line stacks DWLS1 and DWLS2 may change.

The sub word line driver blocks SWD_B1 and SWD_B2 may include first sub word line driver block SWD_B1 and a second sub word line driver block SWD_B2. Each of the first sub word line driver block SWD_B1 and the second sub-word line driver block SWD_B2 may include a plurality of PMOSFETs PMOS and a plurality of NMOSFETs NMOS. The first sub word line driver block SWD_B1 and the second sub word line driver block SWD_B2 may share NMOSFETs NMOS. In other embodiments, the NMOSFETs NMOS of the first sub-word line driver block SWD_B1 and the NMOSFETs NMOS of the second sub-word line driver block SWD_B2 may be disposed adjacent to each other.

The first sub word line driver block SWD_B1 and the second sub word line driver block SWD_B2 may each include a plurality of sub word lines SWL. The sub word lines SWL of the first sub word line driver block SWD_B1 and the sub word lines SWL of the second sub word line driver block SWD_B2 may be disposed at the same level. The sub word lines SWL and the double word lines DWL11 to DWL14 and DWL21 to DWL24 may cross each other. Referring to FIGS. 6 and 7, each of the sub word lines SWL may be electrically connected to NMOSFETs and PMOSFETs, and individual sub word lines SWL and individual double word lines DWL11 to DWL14 and DWL21 to DWL24 may be connected to each other.

The sub word lines SWL and the double word lines DWL11 to DWL14 and DWL21 to DWL24 may be electrically connected to each other through the interconnections ICT.

The present invention described above is not limited to the above-described embodiments and the accompanying drawings, and it will be apparent to those skilled in the art that various substitutions, modifications, and changes may be made thereto without departing from the spirit and scope of the present invention.

What is claimed is:

1. A semiconductor memory device, comprising:
a memory cell array including a word line stack including word lines vertically stacked; and
a sub word line driver block including sub word lines disposed below an end portion of the word line stack,
wherein the word lines and the sub word lines extend in directions, respectively, crossing each other.

2. The semiconductor memory device of claim 1, wherein the word line stack is disposed at a higher level than the sub word lines.

3. The semiconductor memory device of claim 1, wherein the end portion of the word line stack has a step structure.

4. The semiconductor memory device of claim 1,
wherein the sub word line driver block includes a plurality of p-type metal-oxide-semiconductor field-effect transistors (PMOSFETs) and a plurality of n-type metal-oxide-semiconductor field-effect transistors (NMOSFETs), the plurality of PMOSFETs and the plurality of NMOSFETs being connected to the sub word lines, and
wherein the PMOSFETs and the NMOSFETs are disposed at a lower level than the sub word lines.

5. The semiconductor memory device of claim 1, wherein the sub word line driver block includes a plurality of sub word line drivers for controlling the word lines of the word line stack, and the sub word line drivers are connected to the sub word lines, respectively.

6. The semiconductor memory device of claim 5,
wherein the word line stack includes a lower-level word line stack and an upper-level word line stack, and
wherein the lower-level word line stack and the upper-level word line stack are connected to different groups of the sub word line drivers.

7. The semiconductor memory device of claim 6,
wherein the different groups of the sub word line drivers include a first group of the sub word line drivers and a second group of the sub word line drivers, and
wherein the first group of the sub word line drivers and the second group of the sub word line drivers share different main word lines.

8. The semiconductor memory device of claim 7, wherein the main word lines have a ‘⊃’ shape.

9. The semiconductor memory device of claim 1, wherein the word lines and the sub word lines of the word line stack are connected to each other through interconnections.

10. The semiconductor memory device of claim 1,
wherein the memory cell array includes a plurality of memory cells, and
wherein each of the memory cells includes:
a laterally oriented active layer;
a vertically oriented bit line connected to one side of the laterally oriented active layer; and
a capacitor connected to another side of the laterally oriented active layer.

11. The semiconductor memory device of claim 10, wherein the capacitor includes a cylinder-type storage node.

12. The semiconductor memory device of claim 10, wherein the laterally oriented active layer includes a thin-body channel having a smaller thickness than each of the word lines.

13. The semiconductor memory device of claim 12, wherein the word lines include a double word line in which two word lines face each other with the thin-body channel interposed therebetween.

14. The semiconductor memory device of claim 12, wherein the thin-body channel includes a semiconductor material or an oxide semiconductor material.

15. The semiconductor memory device of claim 12, wherein the thin-body channel includes polysilicon, germanium, silicon-germanium, or IGZO (Indium Gallium Zinc Oxide).

16. The semiconductor memory device of claim 10, wherein the memory cells are Dynamic Random-Access Memory (DRAM) cells.
